(19) United States
(12) Patent Application Publication
(10) Pub. No.: US 2006/0220006 A1
(43) Pub. Date: Oct. 5, 2006

(54) Molecular-doped transistor and sensor

(76) Inventors: Yong Chen, Sherman Oaks, CA (US); James W. Stasiak, Lebanon, OR (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/096,656

(22) Filed: Apr. 1, 2005

(51) Int. Cl. H01L 29/08

(52) U.S. Cl. 257/40

(57) ABSTRACT

Molecular-doped devices, including transistors and sensors, for nano-scale applications are provided. The device comprises a substrate, a source and a drain, both supported on the substrate and separated by a distance. The molecular-doped device further comprises a layer or wire of a semiconductor material formed on the substrate between the source and drain and a layer of a molecular-doped polymer formed on the semiconductor layer.

### TECHNICAL FIELD

The present invention is directed transistors and sensors that incorporate molecular materials.

### BACKGROUND ART

The traditional solid state (e.g., silicon-based) transistor is made from a semiconductor material; and as shown in FIG. 1A, the silicon-based transistor 100 comprises a semiconductor substrate 102, on which is formed a source 104 and a drain 106. A dielectric layer (e.g., oxide) 108 is formed between the source 104 and the drain 106, and a gate 110 is formed on the dielectric layer. The electric carriers in the semiconductor 104 between the source 104 and drain 106 are influenced by the voltage applied on the gate 110; in other words, the conductance between the source 104 and drain 106 is controlled by the gate voltage.

The traditional polymer transistor is made from a polymer; and as shown in FIG. 1B, the polymer-based transistor 150 comprises a gate 160, on which is formed a dielectric layer 158. A source 154 and drain 156 are formed on the dielectric layer 158. A layer 162 of molecules or a polymer is formed on the dielectric layer 158, between the source 154 and drain 156. The electric carriers in the polymer layer 162 between the source 154 and drain 156 are influenced by the voltage applied on the gate 160; in other words, the conductance between the source 154 and drain 156 is controlled by the gate voltage.

When the semiconductor transistor 100 is reduced down to nanometer scale, the gate 110 can hardly control the current between the source 104 and drain 106 with electric field through dielectric layer 108. On the other hand, for polymer transistors 150, a high gate voltage is needed to change the carrier density and thus the source/drain 154/156 conductance in the polymer 162. The conductance and mobility for the polymer 162 is low; therefore, the speed of the transistor 150 is low.

What is needed is a transistor having nanometer-scale dimensions that avoids most, if not all, of the aforementioned prior art problems.

### DISCLOSURE OF INVENTION

In accordance with an embodiment disclosed herein, a molecular-doped device for nano-scale applications is provided. The device comprises a substrate and a source and a drain, both supported on the substrate and separated by a distance. The molecular-doped device further comprises a layer or wire of a semiconductor material formed on the substrate between the source and drain and a layer of a molecular-doped polymer formed on the semiconductor layer or wire.

In accordance with another embodiment disclosed herein, a molecular-doped transistor for nano-scale applications is provided. The transistor comprises the substrate and the source and drain, both supported on the substrate and separated by a distance. The molecular-doped transistor further comprises the layer or wire of semiconductor material formed on the substrate between the source and drain, the layer of molecular-doped polymer formed on the semiconductor layer or wire, and a gate formed on a portion of the molecular-doped polymer layer.

In accordance with yet another embodiment disclosed herein, a method of sensing a phenomenon is provided. The method comprises:

providing the molecular-doped device for nano-scale applications, the molecular-doped device comprising the substrate and the source and drain, both supported on the substrate and separated by a distance, the molecular-doped device further comprising the layer or wire of semiconductor material formed on the substrate between the source and drain and the layer of molecular-doped polymer formed on the semiconductor layer or wire, the molecular-doped polymer having a charge distribution;

introducing the phenomenon to the molecular-doped device so as to influence the charge distribution in the molecular-doped polymer, which thereby changes a current in the semiconductor layer between the source and drain; and

measuring the change in the current.

In accordance with still another embodiment disclosed herein, a method of amplifying a signal is provided. The method comprises:

providing the molecular-doped transistor for nano-scale applications, the molecular-doped transistor comprising the substrate and the source and drain, both supported on the substrate and separated by a distance, the molecular-doped device further comprising the layer or wire of semiconductor material formed on the substrate between the source and drain, the layer of molecular-doped polymer formed on the semiconductor layer or wire, and the gate formed on a portion of the molecular-doped polymer, the semiconductor layer having an electric carrier density and the molecular-doped polymer having a charge distribution, wherein the current between the source and drain is determined by the electric carrier density in the semiconductor layer, which in turn is influenced by the charge distribution in the molecular-doped polymer; and

changing the charge distribution in the molecular-doped polymer by applying an electric field on the gate, thereby influencing the current/resistance between the source and drain.

### BRIEF DESCRIPTION OF THE DRAWINGS

FIG. 1A is a cross-sectional view of a conventional semiconductor-based transistor;

FIG. 1B is a cross-sectional view of a conventional polymer transistor;

FIG. 2A is a cross-sectional view of a molecular-doped polymer transistor in accordance with an embodiment;

FIG. 2B is a cross-sectional view of a molecular-doped polymer sensor in accordance with another embodiment; and

FIGS. 3A-3C are each energy diagrams depicting (a) the different Fermi levels due to the separation of a semiconductor layer from a polymer layer, (b) the result of bringing the two layers into contact to form a depletion layer, and (c) the creation of trapping sites due to the molecular-doped polymer layer for an embodiment of the present invention.

### BEST MODES FOR CARRYING OUT THE INVENTION

Reference is made now in detail to specific embodiments, which illustrates the best mode presently contemplated by the inventors for practicing the invention. Alternative embodiments are also briefly described as applicable.

Definitions.

As used herein, the term “self-aligned” as applied to “junction” means that the junction that forms the switch and/or other electrical connection between two wires is created wherever two wires, either of which may be coated or functionalized, cross each other, because it is the act of crossing that creates the junction.

The term “self-assembled” as used herein refers to a system that naturally adopts some geometric pattern because of the identity of the components of the system; the system achieves at least a local minimum in its energy by adopting this configuration.

The term “singly configurable” means that a switch can change its state only once via an irreversible process such as an oxidation or reduction reaction; such a switch can be the basis of a programmable read only memory (PROM), for example.

The term “reconfigurable” means that a switch can change its state multiple times via a reversible process such as an oxidation or reduction; in other words, the switch can be opened and closed multiple times such as the memory bits in a random access memory (RAM).

The term “configurable” means either “singly configurable” or “reconfigurable”.

The term “bi-stable” as applied to a molecule means a molecule having two relatively low energy states. The molecule may be either irreversibly switched from one state to the other (singly configurable) or reversibly switched from one state to the other (reconfigurable).

Micron-scale dimensions refers to dimensions that range from 1 micrometer to a few micrometers in size.

Sub-micron scale dimensions refers to dimensions that range from 1 micrometer down to 0.04 micrometers.

Nanometer scale dimensions refers to dimensions that range from 0.1 nanometers to 50 nanometers (0.05 micrometers).

Micron-scale and submicron-scale wires refers to rod or ribbon-shaped conductors or semiconductors with widths or diameters having the dimensions of 1 to 10 micrometers, heights that can range from a few tens of nanometers to a micrometer, and lengths of several micrometers and longer.

A crossbar is an array of switches that connect each wire in one set of parallel wires to every member of a second set of parallel wires that intersects the first set (usually the two sets of wires are perpendicular to each other, but this is not a necessary condition).

“HOMO” is the common chemical acronym for “highest occupied molecular orbital”, while “LUMO” is the common chemical acronym for “lowest unoccupied molecular orbital”. HOMOs and LUMOs are responsible for electronic conduction in molecules and the energy difference, or gap (ΔE_{HOMO/LUMO}), between the HOMO and LUMO and other energetically nearby molecular orbitals is responsible for the electronic conduction properties of the molecule.

Structure of MDP Transistor and Sensor.

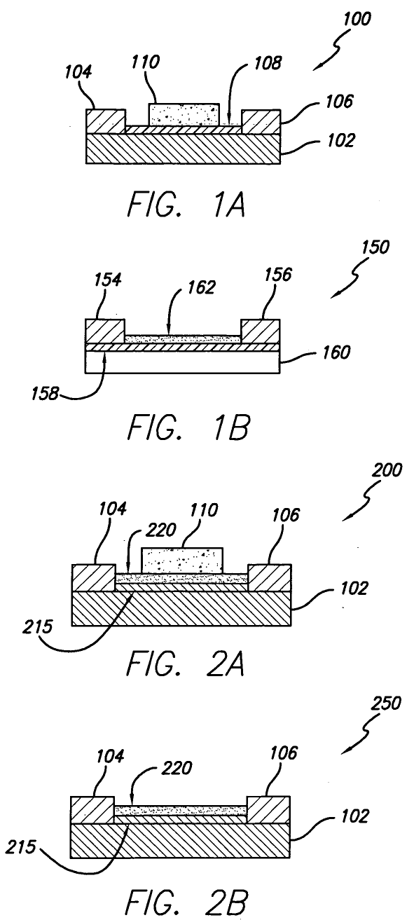

In accordance with the teachings herein, a molecular-doped polymer (MDP) transistor is provided, having the device structure shown in FIG. 2A. The structure 200 shown in FIG. 2A is analogous to that of FIG. 1A, but includes semiconductor layer 215 and a molecular-doped polymer layer 220 on the semiconductor layer in place of the dielectric layer 108. The source 104 and drain 106 are separated by a distance in the range of nanometers to microns; in an embodiment, the source and drain are separated by a distance within the range of about 1 to 1,000 nm. The current between the source 104 and drain 106 is determined by the electric carrier density in the semiconductor layer (or wire) 215, which is in turn influenced by the charge distribution in the MDP layer 220 over the semiconductor layer. The charge distribution in the MDP layer 220 can be changed by applying an electric field on the gate 110; in this way, the current/resistance between the source 104 and drain 106 can be influenced by the voltage on the gate 110.

The semiconductor layer (or wire) 215 has a “functional dimension”, by which is meant the dimension that controls the operation of the device 200. In the case of a layer, that functional dimension is its thickness, while in the case of a wire, that dimension is its diameter. In either case, the functional dimension of the semiconductor layer (or wire) 215 is in the range of nanometers to microns; in an embodiment, the functional dimension is within a range of about 1 to 1,000 nm.

In a similar way, if there is no gate (FIG. 2B), but the charge distribution in the MDP layer 220 can be influenced by an optical field, a chemical ambient, a biological ambient, or a mechanical force, etc, then the current in semiconductor layer (or wire) 215 between the source 104 and drain 108 can be changed accordingly. As a result, the device can function as an optical, chemical, biological, or mechanical sensor. The device 250 shown in FIG. 2B comprises the substrate 102 supporting the source 104 and drain 106. The semiconductor layer 215 is formed on the substrate 102 between the source 104 and drain 106. The MDP layer 220 is formed on the semiconductor layer 215.

The materials comprising the substrate 102, source 104, drain 106, and gate 110 are conventional and well known in transistor technology. The semiconductor layer 215 (or wire) 215 typically comprises any of the Group IV semiconductors, such as silicon or germanium; SiC; any of the Group III-V compound semiconductors, such as AlP, AlAs, AlSb, GaN, GaP, GaAs, GaSb, InP, InAs, and InSb; the Group II-VI compound semiconductors, such as ZnO, ZnS, ZnSe, ZnTe, CdS, CdSe, CdTe, and HgS; and the Group IV-VI compound semiconductors, such as PbS, PbSe, and PbTe, as well as the binary, ternary, and quaternary alloys, such as Si₍₁₋ₓ₎Geₓ, AlₓGa₍₁₋ₓ₎As, Cd₍₁₋ₓ₎MnₓTe, GaAs₍₁₋ₓ₎Pₓ, GaₓIn₍₁₋ₓ₎As, GaₓIn₍₁₋ₓ₎P, Hg₍₁₋ₓ₎CdₓTe, AlₓGa₍₁₋ₓ₎As_{y}Sb_{(1-y)}, and GaₓIn₍₁₋ₓ₎As_{(1-y)}P_{y}, where x (and y, if present) ranges (or range) from 0 to 1. In an embodiment, x (and y, if present) ranges (or range) from slightly more than 0 to slightly less than 1, as is known in the art.

The semiconductor layer 215 may be intentionally doped or undoped. If intentionally doped, the doping range typically depends on the materials comprising this layer (or wire), but is generally in the range of 10¹⁵ to 10²¹ cm⁻³. The films can be doped or undoped at levels required for the specific application (ranging from intrinsic doping to >10²¹ cm⁻³) and having thickness required for the specific application.

The layer (wire) 215 may be deposited by any of the conventional semiconductor deposition techniques, including, but not limited to, vapor (gas) phase, thermal deposition, sputtering, laser ablation, etc. Such methods of deposition include all the conventional methods, including, but not limited to, chemical vapor deposition, epitaxy, atomic layer deposition, sputtering, etc.

Examples of the polymers suitable for the molecular-doped polymer layer 220 include, but is not limited to, polyaniline (PANi), substituted polyaniline or block copolymers of polyaniline; polypyrrole (Ppy), substituted polypyrrole or block copolymers of polypyrrole; polythiophene (PT), substituted polythiophene or block copolymers of polythiophene; polyisothianaphthene (PITN), substituted polyisothianaphthene or block copolymers of polyisothianaphthene; polyparaphenylene (PPP), substituted polyparaphenylene or block copolymers of polyparaphenylene; polythienylene vinylene (PTV), substituted polythienylene vinylene or block copolymers of polythienylene vinylene; polyparaphenylene vinylene (PPV), substituted polyparaphenylene vinylene or block copolymers of polyparaphenylene vinylene; polyacetylene (PA), substituted polyacetylene or block copolymers of polyacetylene; and poly(phenylene sulfide) (PPS), substituted poly(phenylene sulfide) or block copolymers of poly(phenylene sulfide), etc.

Additional examples include, but are not limited to, polymer binders such as poly(styrenes), poly(vinyl chloride), poly(vinyl 3-bromobenzoate), poly(methyl methacrylate), poly(n-propyl methacrylate), poly(isobutyl methacrylate), poly(1-hexyl methacrylate), poly(benzyl methacrylate), bisphenol-A polycarbonate, bisphenol-Z polycarbonate, polyacrylate, poly(vinyl butyral), polysulfone, polyphosphazine, polysiloxane, polyamide nylon, polyurethane, sol gel silsesquioxane, phenoxy resin, etc.

For doping the polymers, an exemplary list of the dopant(s) useful in the practice of the present embodiments includes, but is not limited to, I₂, Br₂, AsF₅, SbF₅, LiAlH₄, NaBH₄, NaH, LiH, CaH₂, butyl lithium, H₂SO₄, HClO₄, KMnO₄, H₂0, toluenesulfonic acid, polystyrene sulfonic acid, organic peracid or mineral peracid, sodium naphthalide, alkali metal or amine salts that contain NO⁺, or NO₂⁺ ions, and triarylsulfonium and diaryliodonium salts, etc. Additional dopants include, but are not limited to, arylalkanes, arylamines, triarylamines, enamines, heterocyclics, hydrazones, carbazoles, polysilylenes, polygermylenes, fluorenones, sulfones, etc.

The concentration of the dopant may influence the physical properties of the doped films. Higher dopant concentrations may “plasticize” the film and may compromise the integrity of the film. Accordingly, in an embodiment, the dopant concentration is in the range of about 1 to 70 wt %. In another embodiment, the polymer layer is doped with the dopant to a value within the range of about 1 to 50 wt %.

The polymer layer 220 is deposited to a thickness in the range of nanometers to micrometers; in an embodiment, the thickness is within the range of about 1 to 1,000 nm. The thickness of the polymer layer 220 is independent of the semiconductor layer (or wire) 215. The polymer layer 220 may be deposited by any of the methods employed for depositing the semiconductor layer (or wire) 215.

It will be appreciated by those skilled in this art that it is the exploitation of the physical and electrical properties of molecular-doped polymers that enables scaling devices to nano dimensions.

Operational Principles.

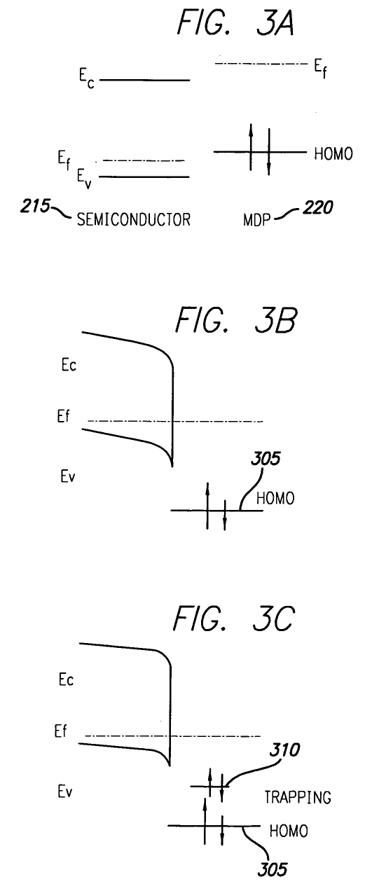

With regard to the transistor structure 200 (with gate), when the semiconductor layer is separated from polymer layer, the layers may have different Fermi levels (FIG. 3A). When they are brought into contact, the Fermi levels will be equalized by moving electrons (or holes) in semiconductor into the polymer layer, resulting in a depletion layer 305 in the semiconductor (FIG. 3B). If the thickness of the depletion layer 305 is comparable with the thickness of the semiconductor layer 215, then the conductance of the semiconductor layer will be changed significantly. The MDP layer 220 will create significant trapping sites 310 for charges inside the polymer layer. When an electric field is applied via the gate 110, the electrons (or holes) can hop between the trapping sites. If charges hop toward (or away from) the sites near the polymer/semiconductor 220/215 interface, then the carrier density in the semiconductor layer 215 will decrease (or increase) accordingly (FIG. 3C). Therefore, the conductance between source 104 and drain 106 can be influenced by the trapping charges in the MDP layer 220 near the MDP/semiconductor 220/215 interface. The trapping charge in turn can be changed by the electric field applied via the gate 110.

With regard to the sensor structure 250 (without gate), the trapping charges in the MDP 220 can also be influenced by an optical field, chemical ambient, biological ambient, or mechanical force, etc. Various MDPs 220 can be selected to maximize the changes of the trapped charges, and therefore the sensitivities of the current between the source 104 and drain 106 via the semiconductor layer 215, to form optical, chemical, biological, or mechanical sensors.

The teachings herein provide a molecular-doped polymer device 200 (transistor), 250 (sensor) that has several advantages over the previous semiconductor and polymer transistors: (1) its speed is higher than that of a conventional polymer transistor; (2) it can be reduced to nanometer scale; (3) it is less expensive than prior art transistors; and (4) it is suitable for high density nanoscale circuits.

### INDUSTRIAL APPLICABILITY

The molecular-doped polymer transistor is expected to find use in a variety of applications, including, but not limited to, nano-scale field effect transistors and sensors based on optical, chemical, biological, and mechanical ambients.

What is claimed is:

1. A molecular-doped device for nano-scale applications, comprising a substrate, a source and a drain, both supported on the substrate and separated by a distance, the molecular-doped device further comprising a layer or wire of a semiconductor material formed on the substrate between the source and drain and a layer of a molecular-doped polymer formed on the semiconductor layer or wire.

2. The molecular-doped device of claim 1 further comprising a gate formed on a portion of the molecular-doped polymer layer.

3. The molecular-doped device of claim 1 wherein the semiconductor material is selected from the group consisting of Group IV elements, Group III-V compound semiconductors, and Group II-VI compound semiconductors.

4. The molecular-doped device of claim 3 wherein the semiconductor material is selected from the consisting of silicon, germanium, SiC, AlP, AlAs, AlSb, GaN, GaP, GaAs, GaSb, InP, InAs, InSb, ZnO, ZnS, ZnSe, ZnTe, CdS, CdSe, CdTe, HgS, PbS, PbSe, PbTe, Si₍₁₋ₓ₎Geₓ, AlₓGa₍₁₋ₓ₎As, Cd₍₁₋ₓ₎MnₓTe, GaAs₍₁₋ₓ₎Pₓ, GaₓIn₍₁₋ₓ₎As, GaₓIn₍₁₋ₓ₎P, Hg₍₁₋ₓ₎CdₓTe, AlₓGa₍₁₋ₓ₎-As_{y}Sb_{(1-y)}, and GaₓIn₍₁₋ₓ₎As_{(1-y)}P_{y}.

5. The molecular-doped device of claim 1 wherein the semiconductor layer has a thickness within a range of about 1 to 1,000 nm thick or wherein the semiconductor wire has a diameter within the same range.

6. The molecular-doped device of claim 1 wherein the molecular-doped polymer comprises (a) a polymer selected from the group consisting of polyaniline, substituted polyaniline, block copolymers of polyaniline, polypyrrole, substituted polypyrrole, block copolymers of polypyrrole, polythiophene, substituted polythiophene, block copolymers of polythiophene, polyisothianaphthene, substituted polyisothianaphthene, block copolymers of polyisothianaphthene, polyparaphenylene, substituted polyparaphenylene, block copolymers of polyparaphenylene, polythienylene vinylene, substituted polythienylene vinylene, block copolymers of polythienylene vinylene, polyparaphenylene vinylene, substituted polyparaphenylene vinylene, block copolymers of polyparaphenylene vinylene, polyacetylene, substituted polyacetylene, block copolymers of polyacetylene, poly(phenylene sulfide), substituted poly(phenylene sulfide), and block copolymers of poly(phenylene sulfide), poly(styrenes), poly(vinyl chloride), poly(vinyl 3-bromobenzoate), poly(methyl methacrylate), poly(n-propyl methacrylate), poly(isobutyl methacrylate), poly(1-hexyl methacrylate), poly(benzyl methacrylate), bis-phenol-A polycarbonate, bisphenol-Z polycarbonate, polyacrylate, poly(vinyl butyral), polysulfone, polyphosphazine, polysiloxane, polyamide nylon, polyurethane, sol gel silsesquioxane, phenoxy resin, and (b) a dopant selected from the group consisting of I₂, Br₂, AsF₅, SbF₅, LiAlH₄, NaBH₄, NaH, LiH, CaH₂, butyl lithium, H₂SO₄, HClO₄, KMnO₄, H₂O, toluenesulfonic acid, polystyrene sulfonic acid, organic peracid or mineral peracid, sodium naphthalide, alkali metal or amine salts that contain NO⁺, or NO₂⁺ ions, triarylsulfonium and diaryliodonium salts, arylalkanes, arylamines, triarylamines, enamines, heterocyclics, hydrazones, carbazoles, polysilylenes, polygermylenes, fluorenones, and sulfones.

7. The molecular-doped device of claim 6 wherein the dopant has a concentration in the polymer within a range of about 1 to 70 wt %.

8. The molecular-doped device of claim 1 wherein the molecular-doped layer has a thickness within a range of about 1 to 1,000 nm thick.

9. The molecular-doped device of claim 1 wherein the distance separating the source and drain is within a range of about 1 to 1,000 nm.

10. The molecular-doped device of claim 1 configured to sense an optical field.

11. The molecular-doped device of claim 1 configured to sense a chemical or biological ambient.

12. The molecular-doped device of claim 1 configured to sense a mechanical force.

13. A molecular-doped transistor for nano-scale applications, comprising a substrate, a source and a drain, both supported on the substrate and separated by a distance, the molecular-doped transistor further comprising a layer or wire of a semiconductor material formed on the substrate between the source and drain, a layer of a molecular-doped polymer formed on the semiconductor layer or wire, and a gate formed on a portion of the molecular-doped polymer layer.

14. The molecular-doped transistor of claim 13 wherein the semiconductor material is selected from the group consisting of Group IV elements, Group III-V compound semiconductors, and Group II-VI compound semiconductors.

15. The molecular-doped transistor of claim 14 wherein the semiconductor material is selected from the consisting of silicon, germanium, SiC, AlP, AlAs, AlSb, GaN, GaP, GaAs, GaSb, InP, InAs, InSb, ZnO, ZnS, ZnSe, ZnTe, CdS, CdSe, CdTe, HgS, PbS, PbSe, PbTe, Si₍₁₋ₓ₎Geₓ, AlₓGa₍₁₋ₓ₎As, Cd₍₁₋ₓ₎MnₓTe, GaAs₍₁₋ₓ₎Pₓ, GaₓIn₍₁₋ₓ₎As, GaₓIn₍₁₋ₓ₎P, Hg₍₁₋ₓ₎CdₓTe, AlₓGa₍₁₋ₓ₎-As_{y}Sb_{(1-y)}, and GaₓIn₍₁₋ₓ₎As_{(1-y)}P_{y}.

16. The molecular-doped transistor of claim 13 wherein the semiconductor layer has a thickness within a range of about 1 to 1,000 nm thick or wherein the semiconductor wire has a diameter within the same range.

17. The molecular-doped transistor of claim 13 wherein the molecular-doped polymer comprises (a) a polymer selected from the group consisting of polyaniline, substituted polyaniline, block copolymers of polyaniline, polypyrrole, substituted polypyrrole, block copolymers of polypyrrole, polythiophene, substituted polythiophene, block copolymers of polythiophene, polyisothianaphthene, substituted polyisothianaphthene, block copolymers of polyisothianaphthene, polyparaphenylene, substituted polyparaphenylene, block copolymers of polyparaphenylene, polythienylene vinylene, substituted polythienylene vinylene, block copolymers of polythienylene vinylene, polyparaphenylene vinylene, substituted polyparaphenylene vinylene, block copolymers of polyparaphenylene vinylene, polyacetylene, substituted polyacetylene, block copolymers of polyacetylene, poly(phenylene sulfide), substituted poly(phenylene sulfide), and block copolymers of poly(phenylene sulfide), poly(styrenes), poly(vinyl chloride), poly(vinyl 3-bromobenzoate), poly(methyl methacrylate), poly(n-propyl methacrylate), poly(isobutyl methacrylate), poly(1-hexyl methacrylate), poly(benzyl methacrylate), bis-phenol-A polycarbonate, bisphenol-Z polycarbonate, polyacrylate, poly(vinyl butyral), polysulfone, polyphosphazine, polysiloxane, polyamide nylon, polyurethane, sol gel silsesquioxane, phenoxy resin, and (b) a dopant selected from the group consisting of I₂, Br₂, AsF₅, SbF₅, LiAlH₄, NaBH₄, NaH, LiH, CaH₂, butyl lithium, H₂S0₄, HClO₄, KMnO₄, H₂O, toluenesulfonic acid, polystyrene sulfonic acid, organic peracid or mineral peracid, sodium naphthalide, alkali metal or amine salts that contain NO⁺, or NO₂⁺ ions, triarylsulfonium and diaryliodonium salts, arylalkanes, arylamines, triarylamines, enamines, heterocyclics, hydrazones, carbazoles, polysilylenes, polygermylenes, fluorenones, and sulfones.

18. The molecular-doped transistor of claim 17 wherein the dopant has a concentration in the polymer within a range of about 1 to 70 wt %.

19. The molecular-doped transistor of claim 13 wherein the molecular-doped layer has a thickness within a range of about 1 to 1,000 nm thick.

20. The molecular-doped transistor of claim 13 wherein the distance separating the source and drain is within a range of about 1 to 1,000 nm.

21. A method of sensing a phenomenon, the method comprising:
providing a molecular-doped device for nano-scale applications, the molecular-doped device comprising a substrate, a source and a drain, both supported on the substrate and separated by a distance, the molecular-doped device further comprising a layer or wire of a semiconductor material formed on the substrate between the source and drain and a layer of a molecular-doped polymer formed on the semiconductor layer or wire, the molecular-doped polymer having a charge distribution;
introducing the phenomenon to the molecular-doped device so as to influence the charge distribution in the molecular-doped polymer, which thereby changes a current in the semiconductor layer between the source and drain; and
measuring the change in the current.

22. The method of claim 21 wherein the phenomenon is selected from the group consisting of optical fields, chemical ambients, biological ambients, and mechanical forces.

23. The method of claim 21 wherein the semiconductor material is selected from the group consisting of Group IV elements, Group II-V compound semiconductors, and Group II-VI compound semiconductors.

24. The method of claim 23 wherein the semiconductor material is selected from the consisting of silicon, germanium, SiC, AlP, AlAs, AlSb, GaN, GaP, GaAs, GaSb, InP, InAs, InSb, ZnO, ZnS, ZnSe, ZnTe, CdS, CdSe, CdTe, HgS, PbS, PbSe, PbTe, Si₍₁₋ₓ₎Geₓ, AlₓGa₍₁₋ₓ₎As, Cd₍₁₋ₓ₎MnₓTe, GaAs₍₁₋ₓ₎Pₓ, GaₓIn₍₁₋ₓ₎As, GaₓIn₍₁₋ₓ₎P, Hg₍₁₋ₓ₎CdₓTe, AlₓGa₍₁₋ₓ₎-As_{y}Sb_{(1-y)}, and GaₓIn₍₁₋ₓ₎As_{(1-y)}P_{y}.

25. The method of claim 21 wherein the semiconductor layer has a thickness within a range of about 1 to 1,000 nm thick or wherein the semiconductor wire has a diameter within the same range.

26. The method of claim 21 wherein the molecular-doped polymer (a) a polymer selected from the group consisting of polyaniline, substituted polyaniline, block copolymers of polyaniline, polypyrrole, substituted polypyrrole, block copolymers of polypyrrole, polythiophene, substituted polythiophene, block copolymers of polythiophene, polyisothianaphthene, substituted polyisothianaphthene, block copolymers of polyisothianaphthene, polyparaphenylene, substituted polyparaphenylene, block copolymers of polyparaphenylene, polythienylene vinylene, substituted polythienylene vinylene, block copolymers of polythienylene vinylene, polyparaphenylene vinylene, substituted polyparaphenylene vinylene, block copolymers of polyparaphenylene vinylene, polyacetylene, substituted polyacetylene, block copolymers of polyacetylene, poly(phenylene sulfide), substituted poly(phenylene sulfide), and block copolymers of poly(phenylene sulfide), poly(styrenes), poly(vinyl chloride), poly(vinyl 3-bromobenzoate), poly(methyl methacrylate), poly(n-propyl methacrylate), poly(isobutyl methacrylate), poly(1-hexyl methacrylate), poly(benzyl methacrylate), bisphenol-A polycarbonate, bisphenol-Z polycarbonate, polyacrylate, poly(vinyl butyral), polysulfone, polyphosphazine, polysiloxane, polyamide nylon, polyurethane, sol gel silsesquioxane, phenoxy resin, and (b) a dopant selected from the group consisting of I₂, Br₂, AsF₅, SbF₅, LiAlH₄, NaBH₄, NaH, LiH, CaH₂, butyl lithium, H₂SO₄, HClO₄, KMnO₄, H₂0, toluenesulfonic acid, polystyrene sulfonic acid, organic peracid or mineral peracid, sodium naphthalide, alkali metal or amine salts that contain NO⁺, or NO₂⁺ ions, triarylsulfonium and diaryliodonium salts, arylalkanes, arylamines, triarylamines, enamines, heterocyclics, hydrazones, carbazoles, polysilylenes, polygermylenes, fluorenones, and sulfones.

27. The method of claim 26 wherein the dopant has a concentration in the polymer within a range of about 1 to 70 wt %.

28. The method of claim 21 wherein the molecular-doped layer has a thickness within a range of about 1 to 1,000 nm thick.

29. The method of claim 21 wherein the distance separating the source and drain is within a range of about 1 to 1,000 nm.

30. A method of amplifying a signal, the method comprising:
providing a molecular-doped device for nano-scale applications, the molecular-doped device comprising a substrate, a source and a drain, both supported on the substrate and separated by a distance, the molecular-doped device further comprising a layer or wire of a semiconductor material formed on the substrate between the source and drain, a layer of a molecular-doped polymer formed on the semiconductor layer or wire, and a gate formed on a portion of the molecular-doped polymer, the semiconductor layer having an electric carrier density and the molecular-doped polymer having a charge distribution, wherein the current between the source and drain is determined by the electric carrier density in the semiconductor layer, which in turn is influenced by the charge distribution in the molecular-doped polymer; and
changing the charge distribution in the molecular-doped polymer by applying an electric field on the gate, thereby influencing the current/resistance between the source and drain.

31. The method of claim 30 wherein the phenomenon is selected from the group consisting of optical fields, chemical ambients, biological ambients, and mechanical forces.

32. The method of claim 30 wherein the semiconductor material is selected from the group consisting of Group IV elements, Group III-V compound semiconductors, and Group II-VI compound semiconductors.

33. The method of claim 32 wherein the semiconductor material is selected from the consisting of silicon, germanium, SiC, AlP, AlAs, AlSb, GaN, GaP, GaAs, GaSb, InP, InAs, InSb, ZnO, ZnS, ZnSe, ZnTe, CdS, CdSe, CdTe, HgS, PbS, PbSe, PbTe, Si₍₁₋ₓ₎Geₓ, AlₓGa₍₁₋ₓ₎As, Cd₍₁₋ₓ₎MnₓTe, GaAs₍₁₋ₓ₎Pₓ, GaₓIn₍₁₋ₓ₎As, GaₓIn₍₁₋ₓ₎P, Hg₍₁₋ₓ₎CdₓTe, AlₓGa₍₁₋ₓ₎-As_{y}Sb_{(1-y)}, and GaₓIn₍₁₋ₓ₎As_{(1-y)}P_{y}.

34. The method of claim 30 wherein the semiconductor layer has a thickness within a range of about 1 to 1,000 nm thick or wherein the semiconductor wire has a diameter within the same range.

35. The method of claim 30 wherein the molecular-doped polymer (a) a polymer selected from the group consisting of polyaniline, substituted polyaniline, block copolymers of polyaniline, polypyrrole, substituted polypyrrole, block copolymers of polypyrrole, polythiophene, substituted polythiophene, block copolymers of polythiophene, polyisothianaphthene, substituted polyisothianaphthene, block copolymers of polyisothianaphthene, polyparaphenylene, substituted polyparaphenylene, block copolymers of polyparaphenylene, polythienylene vinylene, substituted polythienylene vinylene, block copolymers of polythienylene vinylene, polyparaphenylene vinylene, substituted polyparaphenylene vinylene, block copolymers of polyparaphenylene vinylene, polyacetylene, substituted polyacetylene, block copolymers of polyacetylene, poly(phenylene sulfide), substituted poly(phenylene sulfide), and block copolymers of poly(phenylene sulfide), poly(styrenes), poly(vinyl chloride), poly(vinyl 3-bromobenzoate), poly(methyl methacrylate), poly(n-propyl methacrylate), poly(isobutyl methacrylate), poly(1-hexyl methacrylate), poly(benzyl methacrylate), bisphenol-A polycarbonate, bisphenol-Z polycarbonate, polyacrylate, poly(vinyl butyral), polysulfone, polyphosphazine, polysiloxane, polyamide nylon, polyurethane, sol gel silsesquioxane, phenoxy resin, and (b) a dopant selected from the group consisting of I₂, Br₂, AsF₅, SbF₅, LiAlH₄, NaBH₄, NaH, LiH, CaH₂, butyl lithium, H₂SO₄, HClO₄, KMnO₄, H₂O, toluenesulfonic acid, polystyrene sulfonic acid, organic peracid or mineral peracid, sodium naphthalide, alkali metal or amine salts that contain NO⁺, or NO₂⁺ ions, triarylsulfonium and diaryliodonium salts, arylalkanes, arylamines, triarylamines, enamines, heterocyclics, hydrazones, carbazoles, polysilylenes, polygermylenes, fluorenones, and sulfones.

36. The method of claim 35 wherein the dopant has a concentration in the polymer within a range of about 1 to 70 wt %.

37. The method of claim 30 wherein the molecular-doped layer has a thickness within a range of about 1 to 1,000 nm thick.

38. The method of claim 30 wherein the distance separating the source and drain is within a range of about 1 to 1,000 nm.
